(19) United States
(12) Patent Application Publication
(10) Pub. No.: US 2003/0086459 A1
(43) Pub. Date: May 8, 2003

(54) Semiconductor laser and optical-electronic device

(75) Inventor: Masayuki Momose, Komoro (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/270,152

(22) Filed: Oct. 15, 2002

(30) Foreign Application Priority Data
Oct. 19, 2001 (JP) 2001-322402

(51) Int. Cl. H01S 5/00

(52) U.S. Cl. 372/45

(57) ABSTRACT

A semiconductor laser element of a 630-nm band wavelength is designed to have an aspect ratio of beam far field pattern of 1.6 or less. The laser element comprises an n-type GaAs substrate having a slope band in part of its main surface, and an n-type cladding layer, an active layer having a quantum well structure of two periods, p-type cladding layers (interposed by a current blocking layer) and a p-type contact layer, which are formed sequentially by being laminated on the substrate main surface, and a p-side and n-side electrodes formed on the contact layer and the substrate rear surface, respectively. The active layer emits a laser beam of a wavelength of 630-nm band from its section of 1-μm width on both end faces of the slope. The well layers of active layer have a tensile strain and the light emission section of active layer is adjoined on both sides thereof by a low-refractivity layer, thereby structuring an effective refractivity waveguide.

### BACKGROUND OF THE INVENTION

The present invention relates to a semiconductor laser element and an optical-electronic device, such as a rotational laser equipment, which incorporates the semiconductor laser element, and particularly to a technique of emitting such a circular-spot laser beam that the aspect ratio (ratio of the vertical to horizontal spread angles) on the cross section of beam far field pattern is close on 1.

In the application field of short-wavelength semiconductor laser (semiconductor laser element) for information processing, efforts are being paid for making a circular-spot laser beam from the viewpoint of effective use of a laser beam. For example, in the field of DVD, efforts are being paid for making the aspect ratio of laser beam far field pattern to be close on 1 in order to increase the recording capacity.

Semiconductor laser of 630-nm band is red in color, and this high-visibility laser is used widely for measuring apparatus of land survey, etc. The rotational laser equipment is an optical-electronic device which projects a laser spot on the wall surface or scans the wall surface with a laser beam across a certain horizontal angle cyclically thereby to form a linear light band.

In regard to AlGaInP-based semiconductor laser elements (red semiconductor laser) of 630-nm band, there have been intense demands of simplifying the optical system which rectifies the beam to have a circular spot. Conventional 630-nm band semiconductor laser elements have aspect ratios (ratio of the vertical spread angle θ⊥ to the horizontal spread angle θ//:θ⊥/θ//) which are as large as 3 or more, and therefore can merely form ellipsoidal beam spots.

A semiconductor laser element of 630-nm band is described in, for example, an article of the publication of Japanese Journal of Applied Physics, Vol.29, No.9, pp.L1669-L1671 (published in 1990). The article mentions a 632.7-nm band semiconductor laser element of θ⊥=35° and θ//=7.8°, which thus has an aspect ratio of 4.49.

Japanese Patent Unexamined Publication No. Hei 8(1996)-264902 discloses a 630-nm band semiconductor laser element which can deal with the return light noise and is characterized by a small oscillation threshold current based on the provision of a tensile strain layer and compressive strain layer for the active layer in a quantum well structure.

### SUMMARY OF THE INVENTION

The conventional 630-nm band semiconductor laser element has a structure as shown in FIG. 21. The semiconductor laser element 80 is fabricated on the main surface of a GaAs substrate 81 of a first conductivity type, e.g., n-type, on which are formed sequentially an n-type cladding layer 82 of AlGaInP, an active layer 83, a p-AlGaInP layer 84 of a second conductivity type (p-type) of AlGaInP, a p-type etching stop layer 85 of AlGaInP and a p-type cladding layer 86 of AlGaInP, with the p-type cladding layer 86 being removed selectively thereafter to leave a stripe pattern of cladding layer 86.

An n-type GaAs (n-GaAs) layer 87 is formed on the p-type etching stop layer 85 on both sides of the striped p-type cladding layer 86, the striped p-type cladding layer 86 and n-GaAs layer 87 are covered with a p-GaAs layer 88, and a p-side electrode 91 and n-side electrode 92 are formed on the p-GaAs layer 88 and the rear surface (bottom surface) of the GaAs substrate 81, respectively. The laser element 80 has its front emission face and back emission face coated with reflection films of certain reflectivities which are not shown in the figure.

However, the conventional semiconductor laser element 80 of this type having a short wavelength is inherently difficult to operate at high temperatures. Its characteristics in terms of optical output, threshold value, efficiency, etc. at the room temperature and high temperatures have been improved based on the increase of total thickness of active layer, the formation of well layers of three periods or more, the application of strain to the well layers, and so on.

In regard to the far field pattern which represents the laser beam spot shape, the vertical spread angle θ⊥ is dependent on the total thickness of active layer, and a 630-nm band semiconductor laser element has θ⊥ of around 30°. The horizontal spread angle θ// is dependent on the width of ridge stripe, and θ// usually ranges from 7° to 9°. Accordingly, the aspect ratio is as large as 3.3 to 4.3, resulting in an ellipsoidal-spot laser beam.

On this account, the conventional 630-nm band semiconductor laser element can merely make an ellipsoidal-spot beam with an aspect ratio of far field pattern of 3 or more. When it is built in an optical-electronic device such as a rotational laser equipment, a complicated beam rectifying optical system is required for the efficient use of laser beam. For example, as shown in FIG. 12B, a laser beam 72 coming out of a semiconductor laser element 71 undergoes the spot shaping with a collimator lens 73 and a beam rectifying optical system 74 each made up of a number of lenses. The complicated beam rectifying optical system using a large number of optical parts raises the manufacturing cost of the rotational laser equipment.

An object of the present invention is to provide a semiconductor laser element of 630-nm band which can have an aspect ratio of beam far field pattern of 1.6 or smaller or possibly 1.2 or smaller.

Another object of the present invention is to provide an optical-electronic device which incorporates a 630-nm band semiconductor laser element, with the beam aspect ratio being made close on 1 so that the device is reduced in size and manufacturing cost.

These and other objects and novel features of the present invention will become apparent from the following description and accompanying drawings.

Among the affairs of the present invention disclosed in this specification, representatives are briefed as follows.

(1) The inventive semiconductor laser element is characterized by comprising a GaAs substrate of a first conductivity type, a cladding layer of the first conductivity type which is made from AlGaInP and formed on the main surface of the GaAs substrate, an active layer which is formed on the cladding layer of the first conductivity type to have a quantum well structure including well layers of GaInP and a barrier layer of AlGaInP, the well layers being tensile strain layers (strain value ranges from −0.1% to −1.5%) of two periods or less and having a total thickness of 25 nm or less, a cladding layer of a second conductivity type which is made from AlGaInP and formed on the active layer, and a contact layer of the second conductivity type which is made from GaAs and formed on the cladding layer of the second conductivity type, with the light emission section of active layer being adjoined by semiconductor layers which are low in refractivity relative to the active layer, thereby structuring an effective refractivity waveguide, the light emission section of active layer emitting from both end faces thereof a laser beam of a wavelength of 630-nm band and an aspect ratio of far field pattern of 1.6 or less.

The GaAs substrate has its main surface stepped across a slope, and the portion of active layer on the slope is the light emission section and the other portion of active layer outside of and on both sides of the light emission section is a low-refractivity semiconductor layer.

The main surface of the GaAs substrate is oblique by 7° from the crystal plane (100) toward the crystal axis [111], and the slope is oblique by 12.5° and is a (411)A-equivalent crystal plane.

Formed between the active layer and the contact layer are a first cladding layer of the second conductivity type which is made from AlGaInP and formed on the active layer, a blocking layer which is made from AlGaInP, while including Zn and Se, and formed on the first cladding layer, and a second cladding layer of the second conductivity type which is made from AlGaInP, higher in carrier concentration than the first cladding layer and formed on the blocking layer, the portion of blocking layer on the slope having the second conductivity type, the other portion of blocking layer outside of the slope having the first conductivity type, thereby functioning as a current blocking layer.

This semiconductor laser element is useful for the light source of a rotational laser equipment (optical-electronic device) for example. The rotational laser equipment is designed to project a laser beam emitted by a semiconductor laser element on to a subject body through a beam rectifying optical system, thereby marking a position on the subject body.

According to the inventive semiconductor laser element:

(a) A laser beam with an accurate wavelength of 630-nm band can be emitted without the need of inclusion of Al due to the formation of tensile strain layers for the well layers which constitute the active layer. Exclusion of Al can accomplish a long-life semiconductor laser element.

(b) The tensile strain GaInP layer produces a tensile strain by having an increased quantity of Ga, a larger band gap of material and a smaller grating constant. This strain dissolves the degeneracy of heavy holes and light holes at the F point (the point at which the number of waves is zero when the band structure of semiconductor is expressed in the wave number domain), and the resulting higher probability of transition provides a gain necessary for laser oscillation even with a smaller operational current density, enabling the reduction of operational current.

(c) The well layers which constitute the active layer are of two periods or less and have a total thickness of 25 nm or less, resulting in a larger beam spot size in the vertical direction and a smaller vertical spread angle θ⊥.

(d) The light emission section has the structure of effective refractivity waveguide by being adjoined on both sides thereof by a low-refractivity layer, resulting in a smaller beam spot size in the horizontal direction and a larger horizontal spread angle θ//.

(e) The aspect ratio of beam far field pattern (vertical spread angle ∝⊥ to horizontal spread angle θ//) can be 1.6 or smaller, or possibly 1.2 or smaller, due to the decrease of θ⊥ and the increase of θ// as mentioned in the above items (c) and (d), and a laser beam with a circular cross section can be released.

(f) The semiconductor laser element has the structure of effective refractivity waveguide, enabling the reduction of loss even with a narrow waveguide and thus the reduction of operational current density. Accordingly, the laser element has a long life.

(g) Due to the near circular far field pattern, the laser element, when used for the light source of a rotational laser equipment, does not necessitate a beam rectifying optical system for converting an ellipsoidal-spot beam into a circular-spot beam, and the equipment can be reduced in size and manufacturing cost.

### BRIEF DESCRIPTION OF THE DRAWINGS

FIG. 1 is a schematic perspective view of the semiconductor laser element based on a first embodiment of this invention;

FIG. 2 is a schematic diagram showing a portion of the semiconductor laser element of this embodiment and semiconductor layers and Al doping rate of this portion;

FIG. 3 is a graph showing the correlation between the PL wavelength and the well width among semiconductor laser elements;

FIG. 4 is a graph showing the correlation between the vertical spread angle θ⊥ of far field pattern and the well width among semiconductor laser elements;

FIGS. 5A, 5B and 5C are cross-sectional diagrams at the fabrication steps of the semiconductor laser element of this embodiment;

FIG. 6 is a schematic cross-sectional diagram of the substrate, showing the formation of a (311)A-equivalent plane based on a variant embodiment;

FIG. 7 is a graph showing the correlation between the threshold value and the strain value among semiconductor laser elements;

FIGS. 8A and 8B are graphs showing the current vs. optical output characteristics of the semiconductor laser element of this embodiment;

FIGS. 9A and 9B are graphs showing the far field pattern of the semiconductor laser element of this embodiment;

FIG. 10 is a graph showing the correlation between the horizontal spread angle θ// of far field pattern and the stripe width Ws, resulting from the semiconductor laser element of this embodiment and the conventional counterpart;

FIG. 11 is a schematic diagram showing the use of a rotational laser equipment which incorporates the semiconductor laser element of this embodiment;

FIGS. 12A and 12B are schematic diagrams showing the beam rectifying optical systems of the rotational laser equipment based on this embodiment and the conventional counterpart, respectively;

FIG. 13 is a schematic perspective view of the semiconductor laser element based on a second embodiment of this invention;

FIG. 14 is a schematic diagram showing part of the semiconductor laser element of this embodiment;

FIGS. 15A and 15B are graphs showing the current vs. optical output characteristics of the semiconductor laser element of this embodiment;

FIGS. 16A and 16B are graphs showing the far field pattern of the semiconductor laser element of this embodiment;

FIG. 17 is a schematic perspective view of the semiconductor laser element based on a third embodiment of this invention;

FIG. 18 is a schematic diagram showing part of the semiconductor laser element of this embodiment;

FIGS. 19A and 19B are graphs showing the current vs. optical output characteristics of the semiconductor laser element of this embodiment;

FIGS. 20A and 20B are graphs showing the far field pattern of the semiconductor laser element of this embodiment; and

FIG. 21 is a schematic perspective view, with partial enlargement being appended, of the conventional semiconductor laser element.

### DETAILED DESCRIPTION OF THE PREFERRED EMBODIMENTS

The embodiments of this invention will be explained with reference to the drawings. Throughout the figures, items having the same functions are referred to by the common symbols, and explanation thereof is not repeated.

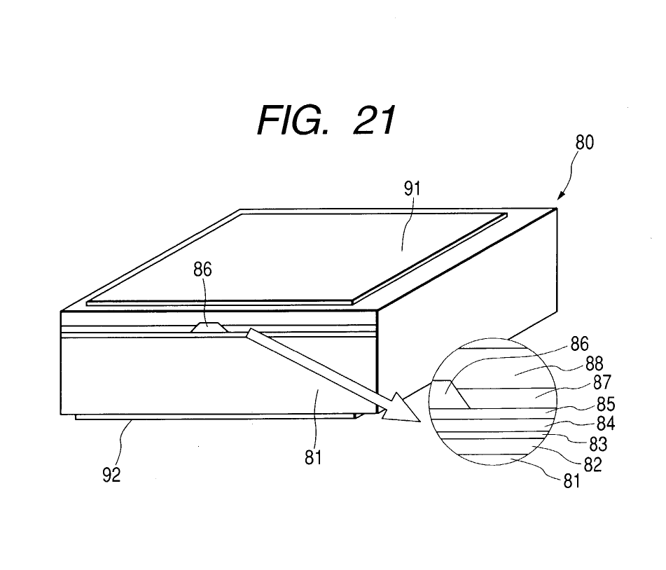

Before entering on the explanation of embodiments, the study conducted by the inventors of the present invention on the scheme of making the aspect ratio to be close on 1 will be reviewed in brief. In order for the conventional element structure shown in FIG. 21 to decrease the aspect ratio, the ridge stripe is narrowed so that the horizontal spread angle θ// increases. The θ// will be increased up to around 12°, which will merely decrease the aspect ratio to about 2.5. The narrowed ridge stripe will increase the light absorption by the n-GaAs current blocking layer (n-GaAs layer 87), resulting in a degraded element characteristics such as the lower efficiency.

From the viewpoint of aspect ratio reduction, the vertical spread angle θ⊥ is reduced after the θ// is brought to 12°. In order to reduce the θ⊥, the total thickness of active layer is reduced by (1) thinning the well layer, or (2) setting the period of well layer to be two periods or less. Specifically, when the total well layer thickness becomes around 25 nm, the θ⊥ will be 22°-24°, and an aspect ratio of around 2 can be attained.

If the scheme (1) of well layer thinning is adopted, the quantum level varies to shorten the wavelength, and a change of well layer strain value is needed so as to bring the wavelength back to 630 nm. Specifically, the well layer must be formed under the condition of smaller strain, and a resulting increase of threshold value will eventually aggravate the high-temperature characteristics.

If the scheme (2) is adopted to reduce the total thickness of active layer, the period of active layer is set to be two periods or less. This element structure has a large light absorption by the n-GaAs current blocking layer, and the active layer of two periods or less will have an increased carrier density per unit volume, resulting in a saturated optical output at high temperatures. Namely, the conventional high-temperature characteristics cannot be retained.

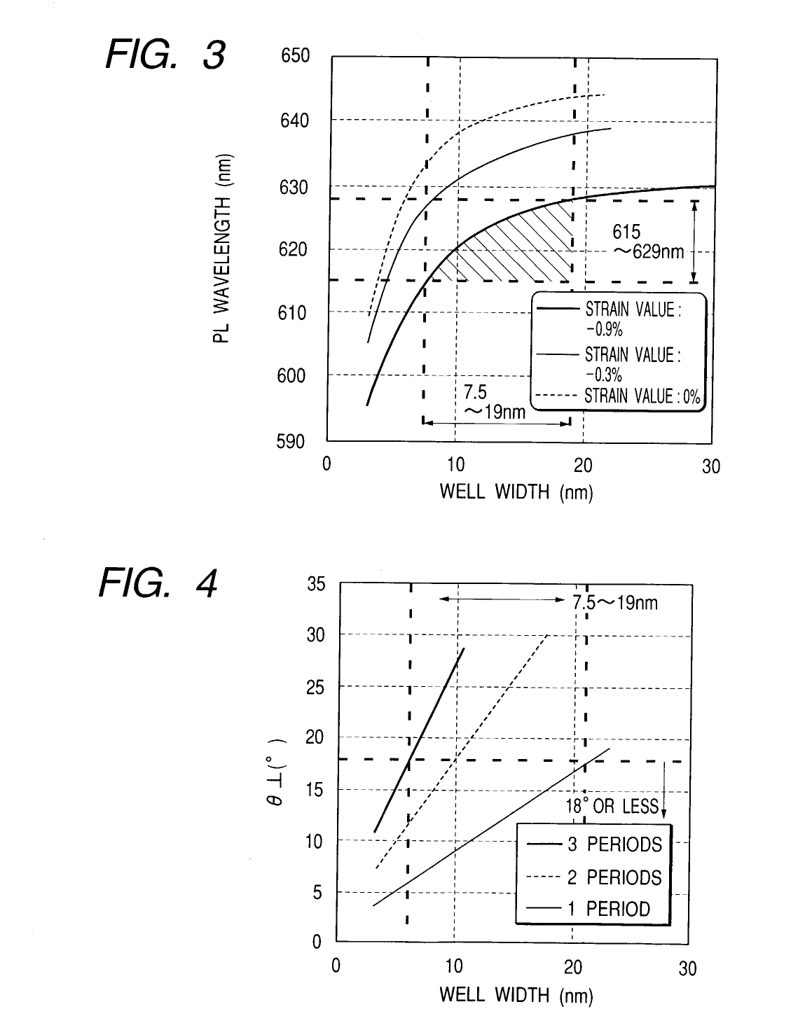

From the viewpoint of laser oscillation wavelength, the following affairs come out. First, FIG. 3 shows the dependency of photoluminescence (PL) wavelength on the well width of active layer. The graph shows the case of −0.9% tensile strain introduced, the case of −0.3% tensile strain introduced, and the case of no strain introduced (0% strain value).

At any strain value, the PL wavelength becomes shorter as the well width becomes narrower. It was confirm by experiment that the laser oscillation wavelength shifts to increase by 10-20 nm relative to the PL wavelength. Therefore, for the setting of a 630-640 nm wavelength, the PL wavelength must be 615-629 nm and accordingly the well width is 4-6 nm in the case of 0% strain value, 4.5-8.5 nm in the case of 0.3% strain value, and 7.5-19 nm in the case of −0.9% strain value.

FIG. 4 shows the correlation between the vertical spread angle θ⊥ and the well width. The θ⊥ increases as the well width increases. When an aspect ratio of 1.5 or less is intended based on the conventional structure in which the horizontal spread angle θ// can be increased merely up to 12°, the θ// must be 18° or less. The well width which enables the θ// of 18° or less is 22 nm or less in the case of a well layer of one period, or 10 nm or less in the case of a well layer of two periods, or 6 nm or less in the case of a well layer of three periods.

Accordingly, an aspect ratio of 1.5 or less is attainable possibly based on the active layer structure with a 6-nm well width, three periods and 0% strain value for example, however, the threshold value will increase to aggravate the laser characteristics unless a tensile strain is introduced. On this account, it was found that the easiest manner of making the aspect ratio to be 1.5 or less while retaining the laser characteristics is the provision of a well layer of two periods or less and the introduction of tensile strain.

Embodiment 1:

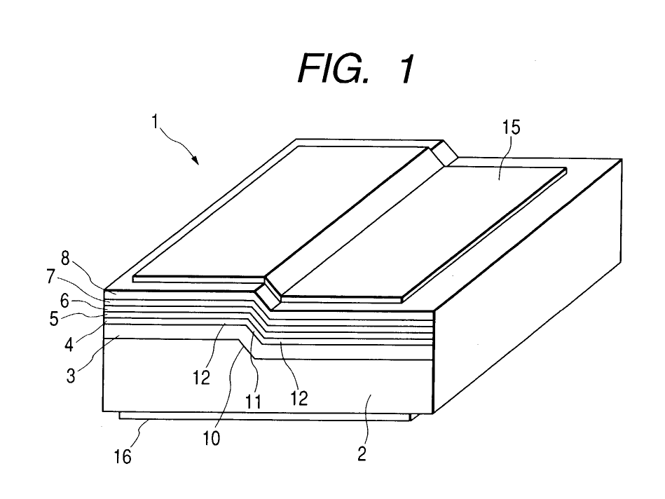

FIG. 1 through FIG. 12 pertain to the semiconductor laser element based on the first embodiment of this invention. This embodiment is a semiconductor laser element of a wavelength of 630-nm band. The first and second conductivity types of semiconductor are n-type(N-type) and p-type(P-type), respectively.

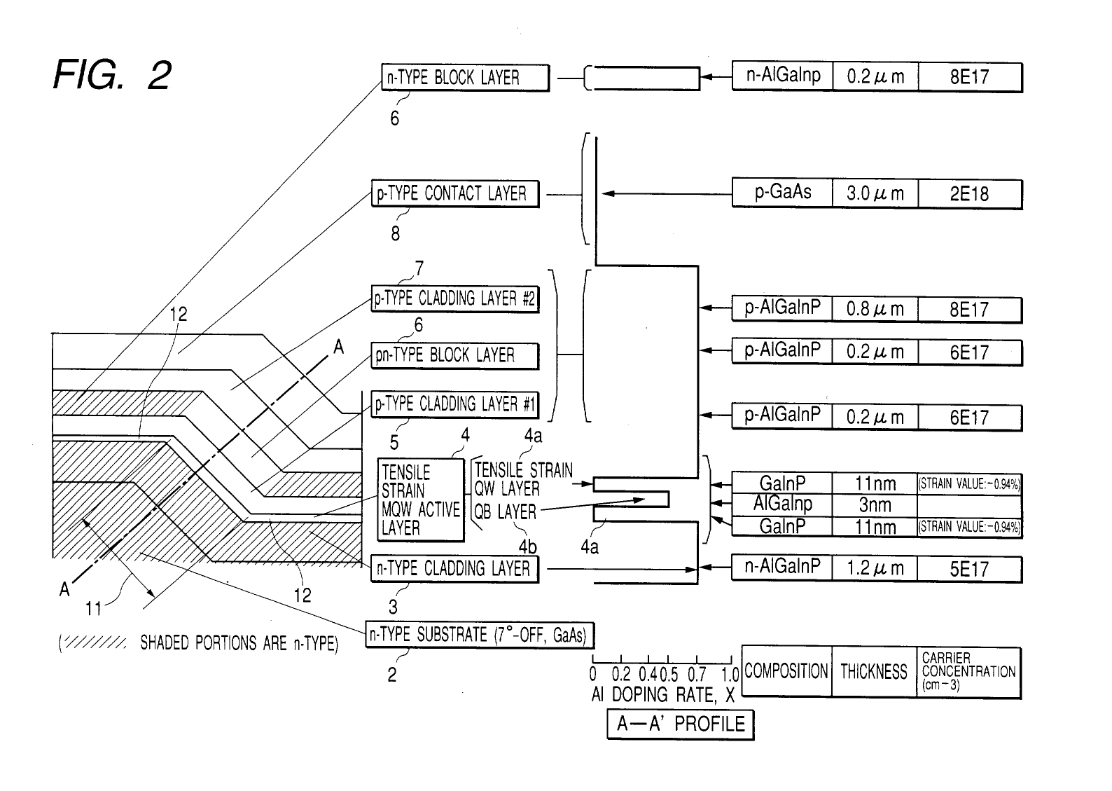

The semiconductor laser element 1 has a structure as shown in FIG. 1 and FIG. 2. FIG. 1 shows the external view of the laser element 1. FIG. 2 shows in the left-hand section the cross section of semiconductor layers, shows in the right-hand section the composition, thickness and carrier concentration of each layer, and shows in the middle section the Al doping rate across the cross section taken along the line A-A. The shaded portions of the cross section are n-type semiconductor.

The laser element 1 is fabricated on an n-type GaAs (n-GaAs) substrate 2. The n-GaAs substrate 2 has its main surface stepped across a slope 10 at the center. The main surface (top surface in the figure) of the n-GaAs substrate 2 is oblique by 7° from the crystal plane (100) toward the crystal axis [111], and the slope is oblique by 12.5°. The slope 10 is equivalent to the (411)A plane. The height of step is around 0.24 μm and the length of slope 10 is around 1.1 μm for example. The slope 10 can alternatively be a (311)A-equivalent plane of 18.2°, instead of 12.5° of the immediate example, and both cases attain the same effectiveness. The slopes of 12.5° and 18.2° are crystal planes which can be obtained stably by the etching process.

The laser element 1 is fabricated by forming semiconductor layers sequentially to laminate on the main surface of the n-GaAs substrate 2 having the slope 10. Specifically, laminated semiconductor layers include an n-type cladding layer 3 of AlGaIn, an active layer 4, a first p-type cladding layer 5 of AlGaInP, a blocking layer 6 of AlGaInP including Zn and Se, a second p-type cladding layer 7 of AlGaInP, and a p-type contact layer 8 of GaAs.

The active layer 4 has a quantum well structure including well layers 4a of two periods which are interposed by a barrier layer 4b. The well layers 4a are undoped GaInP layers and the barrier layer 4b is an undoped AlGaInP layer as shown in FIG. 2. Although in this example, the n-type cladding layer 3 and first p-type cladding layer 5 on each well layer 4a also work as barrier layers, independent barrier layers may be formed separately.

Based on the (311)A plane equivalence of the slope 10, the portion of active layer 4 on the slope 10 becomes a light emission section 11 as shown in FIG. 2, and the semiconductor layers below and above the emission section 11 are the n-type cladding layer 3 and p-type cladding layer 5 which are low-refractivity semiconductor layers. The light emission section 11 has a refractivity of around 3.55, and the n-type cladding layer 3 and p-type cladding layer 5 have a refractivity of around 3.24. The blocking layer 6 which includes Zn and Se is partly p-type in its section on the slope 10 and partly n-type in its section outside the slope 10, thereby being a pn-type blocking layer.

Formed above the p-type contact layer 8 is a p-side electrode 15, and formed on the rear surface of the n-GaAs substrate 2 is an n-side electrode 16. The laser element 1 is a rectangular solid having a length of 600 μm along the waveguide (resonator), a width of 300 μm and a thickness (height) of 100 μm.

The waveguide (resonator) has its one emission face (front emission face) coated with a reflection film which is formed of a single-layer SiO₂ film to have 30% reflectance and its another emission face (back emission face) coated with a reflection film which is formed of a multilayer SiN/SiO₂ film to have 90% reflectance, although these reflection films are not shown in the figures.

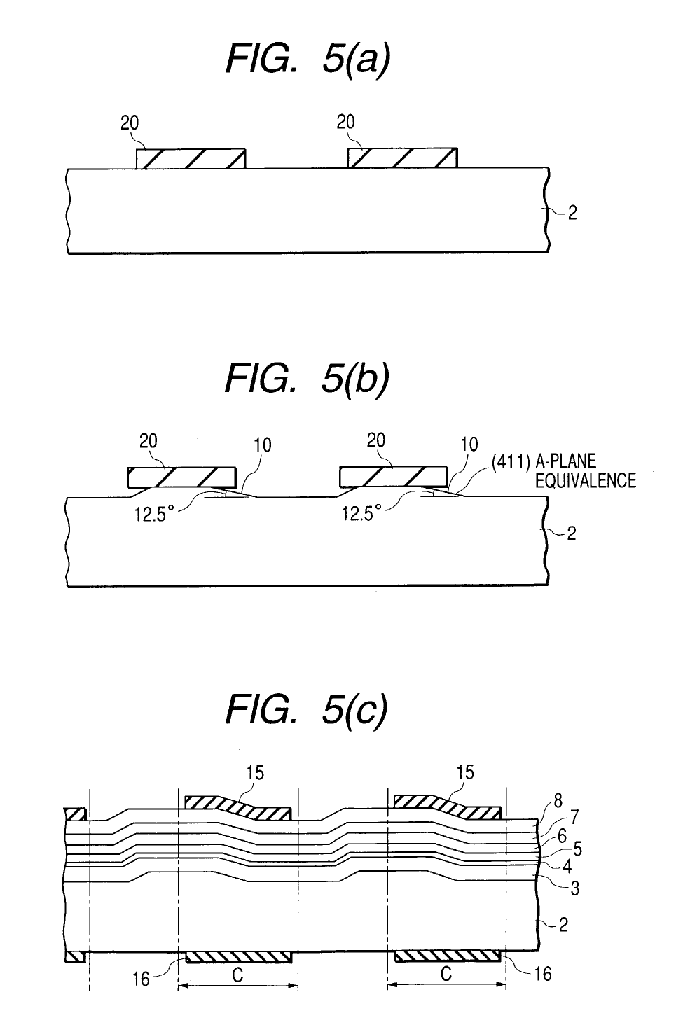

Fabrication of this semiconductor laser element 1 is as follows. An n-type GaAs substrate 2 is prepared as shown in FIG. 5A. The main surface (upper surface) of the substrate 2 is oblique by 7° from the (001) plane of crystal toward the [111]A direction of crystal (this oblique plane will be termed “7°-off plane”).

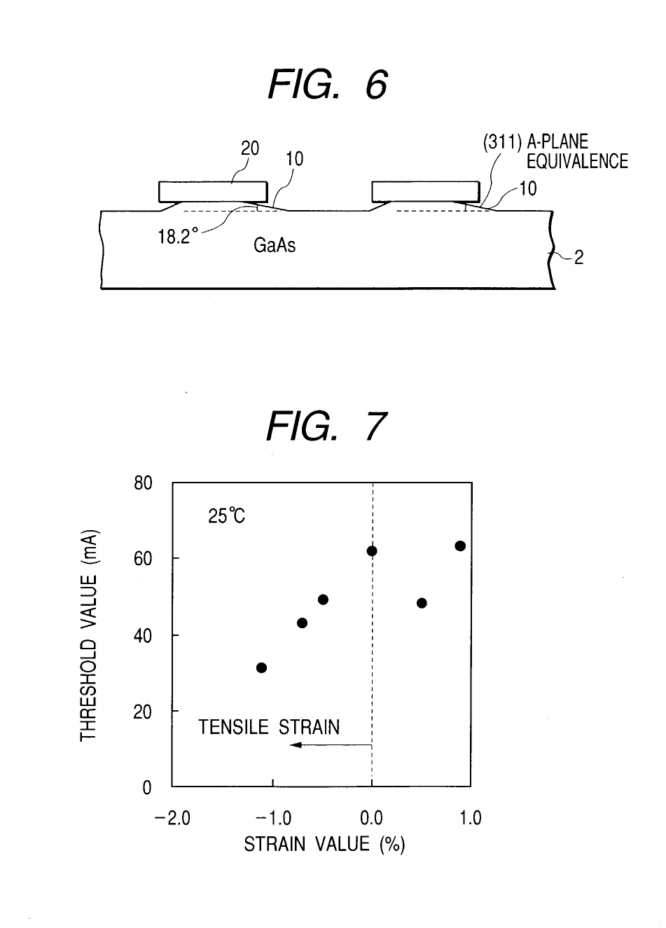

On the main surface of the substrate 2, a photoresist mask 20 of a stripe is formed to extend in the [01-1] direction of crystal. The substrate 20 is treated by wet etching with hydrofluoric acid based etching liquid, thereby forming a slope 10 as shown in FIG. 5B. The slope 10 has different angles on both sides of the photoresist mask 20. Specifically, one slope is a crystal plane such as a (411)A-equivalent plane of 12.5° or (311)A-equivalent plane of 18.2° as determined from the etching condition, and it can be formed stably. FIG. 6 shows a slope of the (311)A-equivalent plane having a slope angle of 18.2°.

This embodiment adopts the (411)A-equivalent plane. The height of step is 0.24 μm and the length of slope 10 is 1.1 μm. A number of slopes 10 are formed at a certain interval.

Next, the photoresist mask 20 is removed, and thereafter the substrate 2 is treated by the organic metal vapor phase growth process (MOCVD process) to form semiconductor layers sequentially in the same chamber, thereby making a multilayer structure as shown in FIG. 5C.

Initially, an n-type cladding layer 3 of n-(AlₓGa1₋ₓ)yIn_{1-y}P is grown. Doping rates x and y are selected from 0.35≦x≦1 and 0.4≦y≦1. The setup of this embodiment is x=0.7 and y=0.53. The n-type cladding layer 3 has a thickness of 1.2 μm and a carrier concentration of 5E17 cm⁻³.

Next, an active layer 4 is formed. The active layer 4 has a multiple quantum well structure, and the quantum well is of two periods as shown in FIG. 2. The well layers 4a are undoped Ga_{z}In_{1-z}P (0.3≦z≦1, e.g., z=0.43) with a thickness of 11 nm. The barrier layer 4b is undoped (AlₓGa1₋ₓ)yIn_{1-y}P (0<x≦1,0.3≦y≦1, e.g., x=0.5, y=0.55) with a thickness of 3 nm. The well layers 4a are of two periods. The undoped Ga_{z}In_{1-z}P layers which become the well layers 4a have a strain value of −0.94%, and it is a tensile strain.

The tensile strain is the state in which the undoped Ga_{z}In_{1-z}P layer has a smaller lattice constant relative to that of the n-GaAs substrate 2. The strain value m is adjusted such that the laser oscillation wavelength ranges from 620 to 645 nm, and it can take a value in the range of 0%<m≦−1.5%.

Next, the n-type cladding layer 3 and the first p-type cladding layer of the same composition are laminated to have a thickness of 0.2 μm and carrier concentration of 6E17 cm⁻³, and the blocking layer 6 of the same composition made from AlGaInP, while including Zn and Se, is further laminated. The blocking layer 6 has a thickness of 0.2 μm, and it is p-type with a carrier concentration of 6E17 cm⁻³ on the slope 10 and is n-type with a carrier concentration of 8E17 cm⁻³ on the 7°-off plane. Consequently, the blocking layer 6 exhibits the p-type conductivity in its section on the slope 10 and exhibits the n-type conductivity in its 7°-off section, thereby functioning as a current blocking layer.

Next, the second p-type cladding layer 7 of the same composition as the first p-type cladding layer 5 is formed to have a thickness of 0.8 μm and carrier concentration of 8E17 cm⁻³.

Next, the p-type contact layer 8 of GaAs is formed to have a thickness of 3 μm and carrier concentration of 2E18 cm³.

Next, the rear surface of the substrate 2 is removed by a prescribed thickness and electrode material is put by vapor deposition on the p-type contact layer 8 and patterned by etching to form the p-side electrode 15 as shown in FIG. 5C. Similarly, electrode material is put by vapor deposition on the rear surface of the substrate 2 and patterned by etching to form the n-side electrode 16.

Next, the substrate 2 is cut at a prescribed interval in the direction perpendicular to the slope 10 extending direction thereby to make tabs (not shown) of 600 μm in width, and both cut faces are coated with different reflection films. A single-layer SiO₂ film (30% reflectance) is formed on one cut face, and a multilayer SiN/SiO₂ film (90% reflectance) is formed on another cut face.

The tabs are further cut at positions shown by the dash-dot lines in FIG. 5C. The range indicated by C defines the width of semiconductor laser element 1, and the rest outside the range is discarded.

This fabrication process yields a number of semiconductor laser elements 1, each of which is 100 μm in thickness, 300 μm in width and 600 μm in length (resonator length), and has a wavelength of 630 nm band.

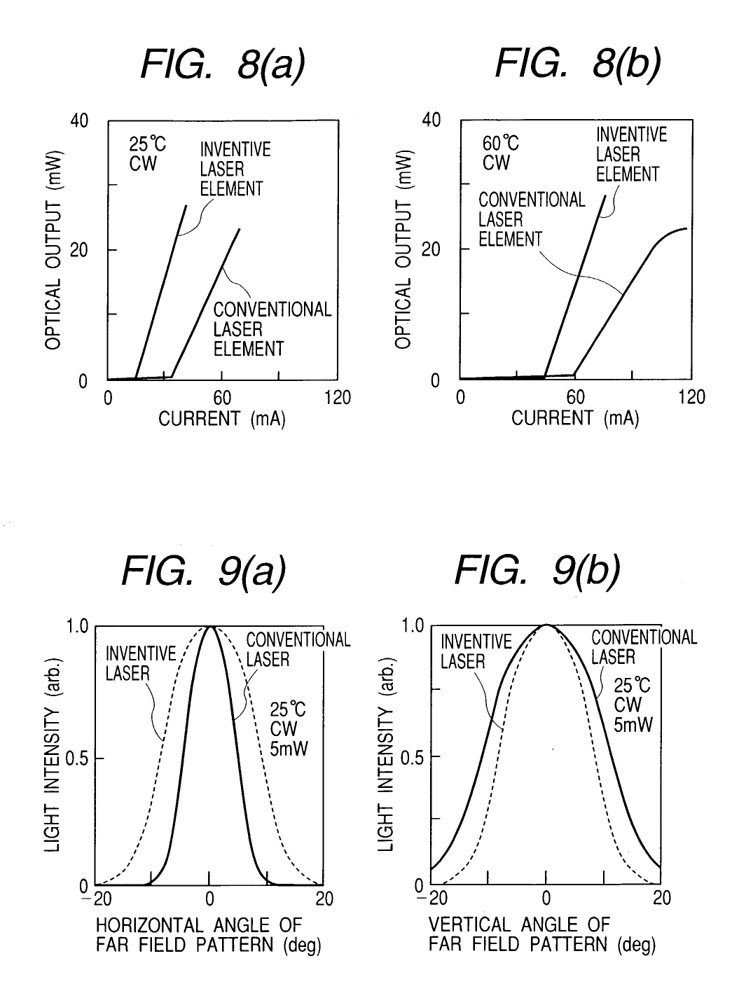

FIGS. 8A and 8B show the current vs. optical output characteristics of the semiconductor laser element 1 at 25° C. and 60° C., respectively. At 25° C. shown in FIG. 8A, the laser element 1 of this embodiment has a threshold value of 15 mA and efficiency of 0.95 W/A, in contrast to the conventional laser element having a threshold value of 34 mA and efficiency of 0.62 W/A. The smaller threshold value of the inventive laser element 1 results from the narrower stripe width and the effective refractivity waveguide structure which suppresses the light absorption. At 60° C. shown in FIG. 8B, the laser element 1 of this embodiment has a threshold value of 41 mA and efficiency of 0.81 W/A, in contrast to the conventional laser element having a threshold value of 58 mA and efficiency of 0.48 W/A. The inventive laser element 1 is superior over the conventional counterpart also at 60° C., which results from the structure of effective refractivity waveguide, while retaining the tensile strain, which reduces the threshold value and improves the efficiency.

FIGS. 9A and 9B show the far field pattern of the semiconductor laser element 1. The far field pattern depicts the laser beam intensity distribution in terms of half-value full-angle. The inventive laser element 1 has a vertical spread angle θ⊥ of 21.3°, in contrast to 30.2° of the conventional laser element. The inventive laser element 1 has a horizontal spread angle θ// of 18.1°, in contrast to 7.4° of the conventional laser element. The inventive laser element 1 has an aspect ratio (θ⊥/θ//) of 1.18, which produces a beam spot close on a true circle, in contrast to 4.08 of the conventional laser element.

The laser oscillation wavelength is 636 nm at 25° C. Consequently, there is accomplished a semiconductor laser element 1 of 630-nm band which produces a beam spot close on a true circle.

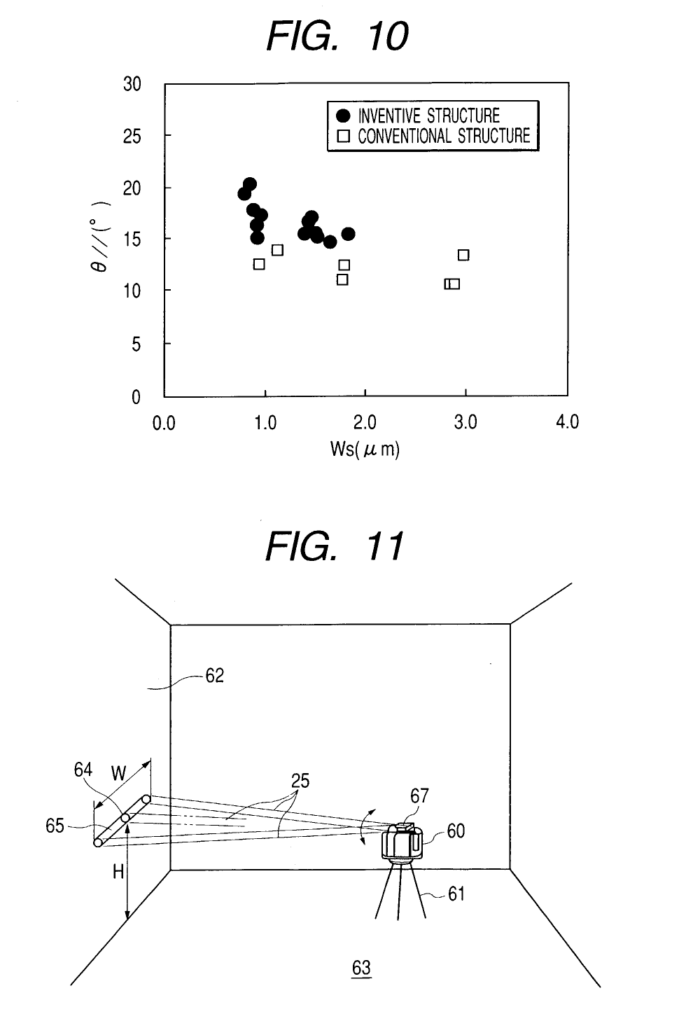

FIG. 10 shows the correlation between the horizontal spread angle θ// of far field pattern and the stripe width Ws, comparing the inventive laser element and the conventional laser element. The graph reveals that the conventional element cannot widen the θ// by narrowing the stripe width. As the basis of this fact, the conventional element has its active layer extending continuously to the outside of light emission section, resulting in a weak effect of light confinement based on different refractivities.

In contrast, according to the inventive structure, the active layer is adjoined on its both sides of light emission section by a material (AlGaInP layer in the present invention) of small refractivity, and a resulting effective refractivity waveguide structure can attain the θ// of 15° or more by having a narrow stripe width. Consequently, the aspect ratio can be reduced, and a semiconductor laser element having an aspect ratio which is close on 1 and a beam spot which is close on a true circle can be accomplished.

The semiconductor laser element 1 of this embodiment will be explained in more detail. The active layer has its well layers set to be two periods or less, and the θ⊥ is reduced to 25° or less from the conventional value of around 3°. This alteration, however, causes the active layer to have an increased carrier density per unit volume, resulting in a saturated optical output at high temperatures.

To cope with this matter, a tensile strain is introduced to the well layers. FIG. 7 shows the result of study on the variation of threshold value caused by the introduction of strain to the well layer. The threshold value decreases in proportion to the amount of tensile strain introduced. FIG. 3 reveals that the necessary well width increases in proportion to the amount of tensile strain. Accordingly, from the viewpoints of threshold value reduction and oscillation wavelength, it is necessary for the achievement of smaller θ⊥ to set the period of active layer to be two periods or less in addition to the introduction of tensile strain.

In consequence, a semiconductor laser element which oscillates at a wavelength of 630-nm band and has a small aspect ratio, small threshold value and small θ⊥ can be accomplished based on the adoption of the active layer structure of two periods or less, the introduction of tensile strain and the formation of wide well layers. Moreover, based on the adoption of the effective refractivity waveguide structure, the light absorption of the conventional buried GaAs structure can be reduced, and in consequence the reduction of threshold value and the improvement of efficiency can be achieved. By setting the stripe width to be 2 μm or less, the θ// can be increased from the conventional 7°-9° to 15°-18°. The increased θ// affects the θ⊥, which decreases from the above-mentioned 25° to practically around 21°-22°. In consequence, a semiconductor laser element of 630-nm band which is characterized by θ⊥=22° and θ//=15° in combination and has an aspect ratio of 1.47 and a beam spot close on a true circle can be accomplish.

When this semiconductor laser element 1 is used as a light source of a rotational laser equipment used in the field of measurement as shown in FIG. 11, the following effectiveness is expected. The rotational laser equipment is designed to release a laser beam, which is reflected by a swing mirror on to the wall surface so that the position of a certain height is marked by the trace of laser beam. The rotational laser equipment 60 which is placed on a tripod 61 projects a laser beam 25 on to the wall surface 62, thereby marking the height H from the floor 63 in the form of a beam spot 64 or a light band 65 of a certain length W. The light band 65 is formed on the wall surface based on the swing of the light projector 67 in the rotational laser equipment 60.

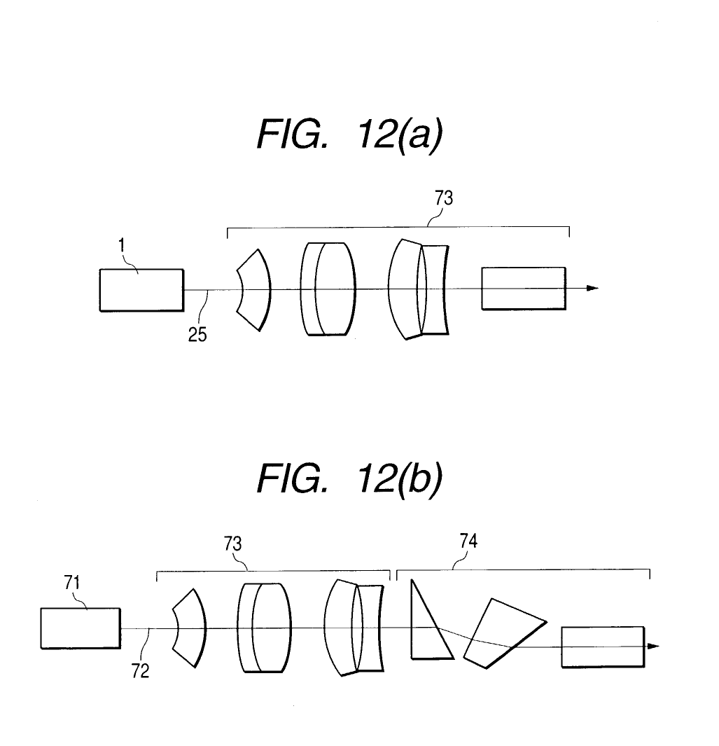

The semiconductor laser element 1 of this embodiment has a beam far field pattern to achieve an aspect ratio of 1.18, producing a beam spot close on a true circle. In consequence, the beam rectifying optical system which is built in the rotational laser equipment 60 can be simply a collimator lens 73 as shown in FIG. 12A in place of the beam rectifying optical system 74 as shown in FIG. 12B used in the conventional rotational laser equipment, whereby the rotational laser equipment 60 can be reduced in size and manufacturing cost.

The semiconductor laser element 1 of this embodiment having a beam far field pattern to achieve an aspect ratio of 1.18 and producing a beam spot close on a true circle is capable of projecting a small clear beam spot 64 or a sharp light band 65 on the floor surface 63.

The foregoing first embodiment of this invention achieves the following effectiveness.

(1) A laser beam with an accurate wavelength of 630-nm band can be emitted without the need of inclusion of Al due to the formation of tensile strain layers for the well layers which constitute the active layer 4. Exclusion of Al can accomplish a long-life semiconductor laser element 1.

(2) The tensile strain GaInP layers (well layers 4a) produce a tensile strain by having an increased quantity of Ga, a larger band gap of material and a smaller grating constant. This strain dissolves the degeneracy of heavy holes and light holes at the Γ point, and the resulting higher probability of transition provides a gain necessary for laser oscillation even with a smaller operational current density, enabling the reduction of operational current.

(3) The quantum well which constitutes the active layer 4 is of two periods or less and the well layers 4a have a total thickness of 25 nm or less, resulting in a larger beam spot size in the vertical direction and a smaller vertical spread angle θ⊥.

(4) The light emission section has the structure of effective refractivity waveguide by being adjoined on both sides thereof by a low-refractivity layer, resulting in a smaller beam spot size in the horizontal direction and a larger horizontal spread angle θ//.

(5) The aspect ratio of laser beam far field pattern can be 1.2 or smaller due to the decrease of θ⊥ and increase of θ// as mentioned in the above items (3) and (4), and a laser beam with a true circular cross section can be emitted.

(6) The semiconductor laser (semiconductor laser element 1) has the structure of effective refractivity waveguide, enabling the reduction of loss even with a narrow waveguide and thus the reduction of operational current density. Accordingly, the laser element 1 has a long life.

(7) Due to the near circular far field pattern, the laser element 1, when used for the light source of a rotational laser equipment, does not necessitate a beam rectifying optical system for converting an ellipsoidal-spot beam into a circular-spot beam, and the equipment can be reduced in size and manufacturing cost.

Embodiment 2:

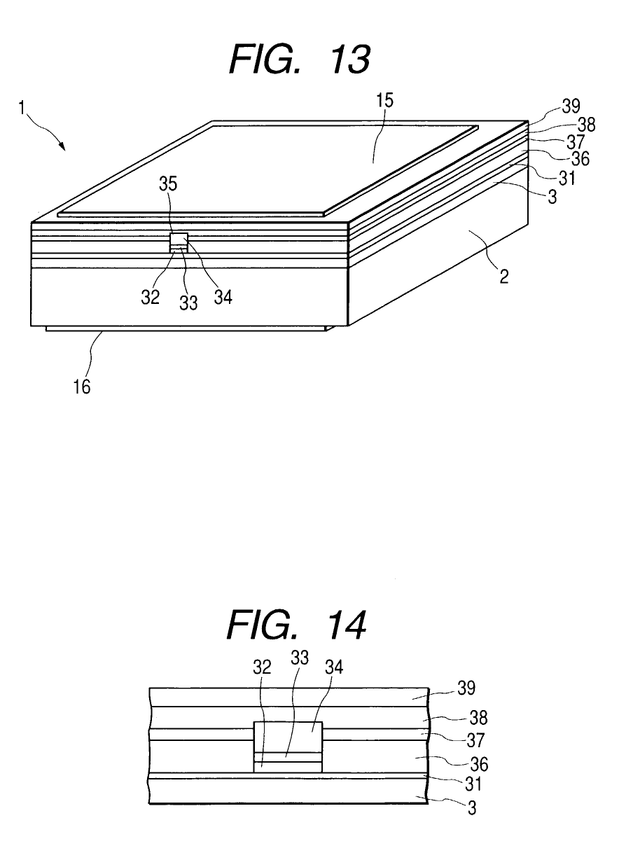

FIG. 13 through FIG. 16 pertain to the semiconductor laser element based on the second embodiment of this invention. This laser element has a buried hetero-structure in which the light emission section of active layer is adjoined on both sides thereof by a low-refractivity semiconductor layer, thereby structuring an effective refractivity waveguide as shown in FIG. 13 and FIG. 14.

The structure and fabrication process of this semiconductor laser element will be explained. As shown in FIG. 13, the laser element 1 is fabricated on an n-GaAs substrate 2 by the MOCVD process. Initially, an n-type cladding layer 3 of n-(AlₓGa1₋ₓ)yIn_{1-y}P (0.35≦x≦=1 and 0.4≦y≦1, e.g., x=0.7 and y=0.53) is grown to have a thickness of 0.8 μm and carrier concentration of 5E17 cm⁻³. Next, an etching stop layer 31 of n-GaᵥIn₁₋ᵥP (v=0.38, thickness:4 nm, carrier concentration:5E17 cm⁻³), a cladding layer 32 of n-(AlₓGa1₋ₓ)yIn_{1-y}P (0.35≦x≦1 and 0.4≦y≦1, e.g., x=0.7 and y=0.53, thickness:0.4 nm, carrier concentration: 5E17 cm⁻³), a two-period active layer 33 of undoped Ga_{z}In_{1-z}P (z=0.46, thickness:9.6 nm) and undoped (AlₓGa1₋ₓ)yIn_{1-y}P (0<x≦1, 0.3≦y≦1, e.g., x=0.5, y=0.55, thickness:3 nm), and a p-type cladding layer 34 of the same composition (AlGaInP) as the n-type cladding layer 3 (thickness:0.3 μm, carrier concentration:6E17 cm⁻³) are laminated. The undoped Ga_{z}In_{1-z}P layers which becomes the well layers has a tensile strain value of −0.86%.

Next, an insulation film of 0.2 μm in thickness is formed on the p-type cladding layer 34, and a stripe of photoresist is formed to have a width of 2 μm on the insulation film (these films are not shown). The insulation film is processed by wet etching with the mask of photoresist stripe so that it is patterned, and the resist film is removed. The p-type cladding layer 34, active layer 33 and n-type cladding layer 32 are etched by dry etching with the mask of insulation film. The etching process stops at the etching stop layer 31. A resulting stripe structure 35 has a width of 1.7 μm. Accordingly, the active layer 33 also has a width of 1.7 μm.

Next, the MOCVD process is conducted again to grow a p-AlGaAs blocking layer 36 of Al_{w}Ga_{1-w}As (0.5≦w≦1, w=0.75, thickness:0.5 μm, carrier concentration:6E17 cm⁻³) and an n-AlGaAs blocking layer 37 of the same composition as the blocking layer 36 (thickness:0.2 μm, carrier concentration:1E18 cm⁻³).

Next, the insulation film (not shown) on the p-type cladding layer 34 is removed by dry etching. The MOCVD process is conducted to grow a p-AlGaInP cladding layer 38 of the same composition (AlGaInP) and same carrier concentration (6E17 cm⁻³) as the p-type layer 34 to have a thickness of 0.8 μm and grow a p-GaAs contact layer 39 to have a thickness of 3.2 μm and carrier concentration of 2E18 cm⁻³.

The p-AlGaAs blocking layer 36, n-AlGaAs blocking layer 37 and p-AlGaInP cladding layer 38 have greater forbidden bands than laser energy radiated from the active layer and therefore these layers do not absorb the laser light. Namely, the structure of effective refractivity waveguide is made by use of these layers, which enhances the emission efficiency as compared with the use of the conventional GaAs buried layer.

Next, a p-side electrode 15 is formed on the p-GaAs contact layer 39, and an n-side electrode 16 is formed on the rear surface of the n-GaAs substrate 2 following the removal of the substrate rear surface by a prescribed thickness.

Next, in the same manner as the first embodiment, the n-GaAs substrate 2 with the formation of multilayer semiconductor is cut into tabs. One cut face for the resonator face (front emission face) is coated with a single-layer SiO₂ film (30% reflectance), and another cut face (back emission face) is coated with a multilayer SiN/SiO₂ film (90% reflectance). The tabs are further cut into pieces to yield semiconductor laser elements 1, each of which is 300 μm in width, 600 μm in length (resonator length) and 100 μm in thickness.

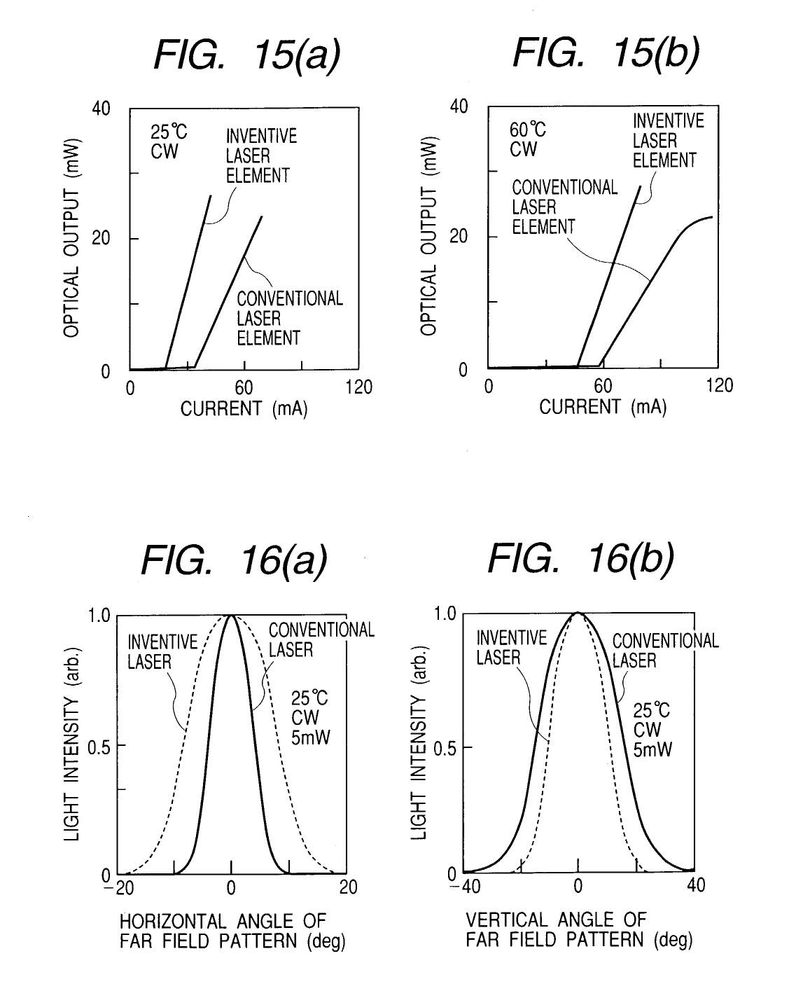

FIGS. 15A and 15B show the current vs. optical output characteristics of the semiconductor laser element 1 at 25° C. and 60° C., respectively. At 25° C., the laser element 1 of this embodiment has a threshold value of 19 mA and efficiency of 1.08 W/A, in contrast to the conventional laser element having a threshold value of 34 mA and efficiency of 0.62 W/A. The smaller threshold value of the inventive laser element 1 conceivably results from the narrower stripe width and the structure of effective refractivity waveguide which suppresses the light absorption. At 60° C., the laser element 1 of this embodiment has a threshold value of 46 mA and efficiency of 0.86 W/A, in contrast to the conventional laser element having a threshold value of 58 mA and efficiency of 0.48 W/A. The inventive laser element 1 is superior over the conventional counterpart also at 60° C., which results from the structure of effective refractivity waveguide, while retaining the tensile strain, which reduces the threshold value and improves the efficiency.

FIGS. 16A and 16B show the far field pattern of the semiconductor laser element 1. The inventive laser element 1 has a horizontal spread angle θ// of 16.3°, in contrast to 7.4° of the conventional laser element. The inventive laser element 1 has a vertical spread angle θ⊥ of 18.2°, in contrast to 30.2° of the conventional laser element. Accordingly, the inventive laser element 1 has an aspect ratio of 1.12, which produces a beam spot close on a true circle, in contrast to 4.08 of the conventional laser element.

The laser oscillation wavelength is 635 nm at 25° C. Consequently, there is accomplished a semiconductor laser (semiconductor laser element 1) of 630-nm band which produces a beam spot close on a true circle.

Embodiment 3:

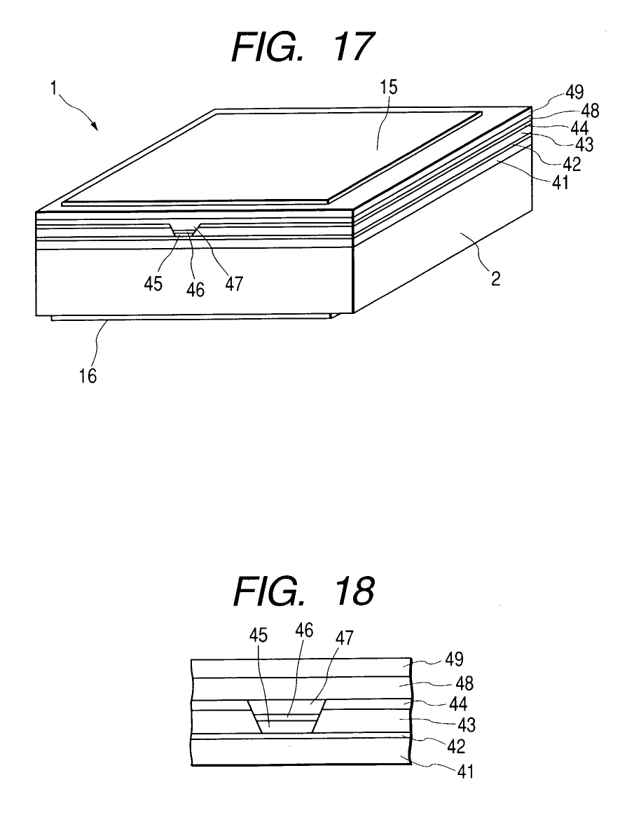

FIG. 17 through FIG. 20 pertain to the semiconductor laser element based on the third embodiment of this invention. This laser element has a structure in which the light emission section of active layer is adjoined on both sides thereof by a low-refractivity semiconductor layer, thereby structuring an effective refractivity waveguide as in the case of the second embodiment.

The structure and fabrication process of this semiconductor laser element 1 will be explained. As shown in FIG. 17, the laser element 1 is fabricated on an n-GaAs substrate 2 by the MOCVD process. Specifically, an n-type cladding layer 41 of n-(AlₓGa1₋ₓ)yIn_{1-y}P (0.35≦x≦1 and 0.4≦y≦1, e.g., x=0.8 and y=0.54, thickness:1.7 μm), an etching stop layer 42 of n-GaᵥIn₁₋ᵥP (v=0.38, thickness:4 nm, carrier concentration: 5E17 cm⁻³), a p-type layer 43 of p-(AlₓGa1₋ₓ)yIn_{1-y}P (0.35≦x≦1 and 0.4≦y≦=1, e.g., x=0.8 and y=0.54, thickness:0.5 μm), and an n-type layer 44 of n-(AlₓGa1₋ₓ)yIn_{1-y}P (0.35<x≦1,0.4≦y≦1, e.g., x=0.8, y=0.54, thickness:0.3 μm, carrier concentration:1E18 cm⁻³) are formed sequentially.

Next, an insulation film of 0.2 μm in thickness is formed on the n-type layer 44, and photoresist is formed on the insulation film and then removed to leave a width of 3 μm (these films are not shown). The n-type layer 44 and p-type layer 43 are etched by wet etching. The etching process stops at the etching stop layer 42. The etched portion has a width of 1.4 μm at the bottom.

Next, the MOCVD process is conducted again to laminate an n-type cladding layer 45 of n-(AlₓGa1₋ₓ)yIn_{1-y}P (0.35≦x≦1 and 0.4≦y≦1, e.g., x=0.8 and y=0.54, thickness:0.3 μm, carrier concentration:5E17 cm⁻³), and an active layer 46 of undoped Ga_{z}In_{1-z}P (z=0.39, thickness:23 nm).

The undoped Ga_{z}In_{1-z}P (z=0.39, thickness:18 nm) of active layer 46 which becomes well layers has a tensile strain value of −1.0%. The active layer 46 has a width of 1.9 μm.

Next, a p-type cladding layer 47 of the same composition as the n-type cladding layer 45 of p-(AlₓGa1₋ₓ)yIn_{1-y}P (0.35≦x≦1 and 0.4≦y≦1, e.g., x=0.8 and y=0.54, thickness:0.5 μm, carrier concentration: 5E17 cm⁻³) is laminated.

Next, the insulation film is removed by wet etching, and the MOCVD process is conducted again to grow a p-type cladding layer 48 of p-AlGaInP (thickness:0.8 μm, carrier concentration:8E17 cm⁻³) and a p-type contact layer 49 of pGaAs.

The active layer 46 is adjoined on both sides thereof by the p-type layer 43 of p-(AlₓGa1₋ₓ)yIn_{1-y}P (x=0.8, y=0.54). Accordingly, a resulting effective refractivity waveguide structure eliminates the light absorption of the conventional GaAs blocking layer, and the improvement of efficiency and the reduction of threshold value can be attained.

Next, a p-side electrode 15 is formed on the p-type contact layer 39, and an n-side electrode 16 is formed on the rear surface of the n-GaAs substrate 2 following the removal of the substrate rear surface by a prescribed thickness.

Next, in the same manner as the first embodiment, the n-GaAs substrate 2 with the formation of multilayer semiconductor is cut into tabs. One cut face for the resonator face (front emission face) is coated with a single-layer SiO₂ film (30% reflectance), and another cut face (back emission face) is coated with a multilayer SiN/SiO₂ film (90% reflectance). The tabs are further cut into pieces to yield semiconductor laser elements 1, each of which is 500 μm in width, 600 μm in length (resonator length) and 100 μm in thickness.

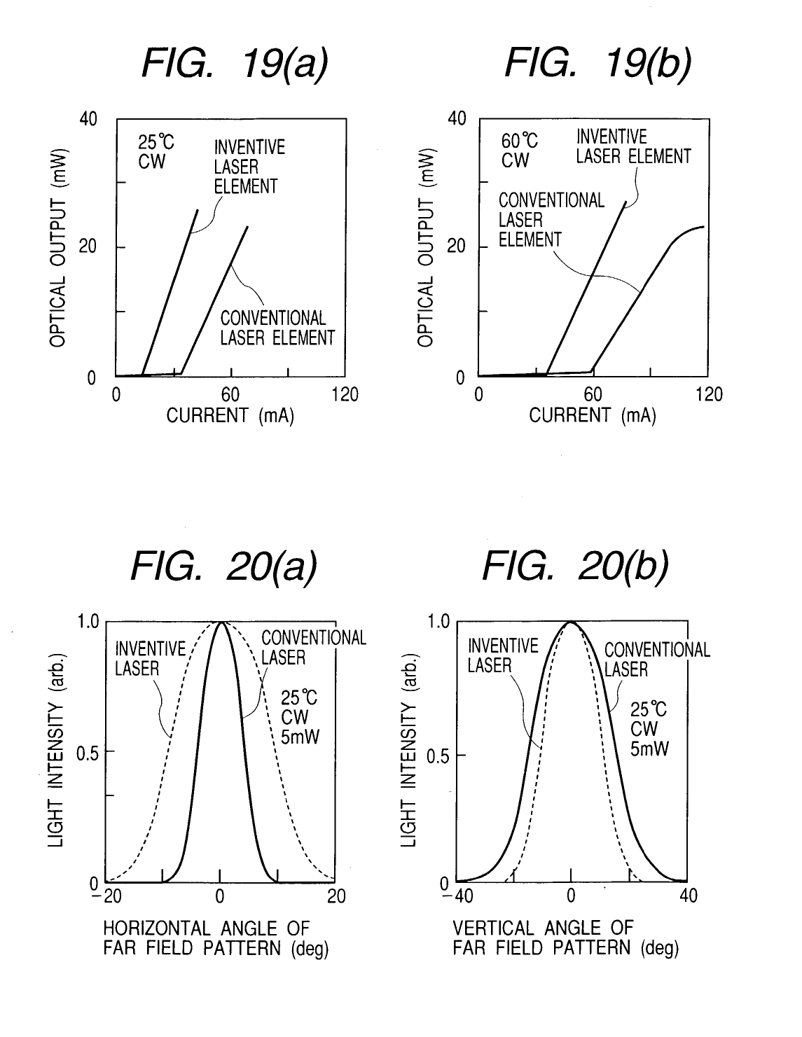

FIGS. 19A and 19B show the current vs. optical output characteristics of the semiconductor laser element 1 at 25° C. and 60° C., respectively. At 25° C., the laser element 1 of this embodiment has a threshold value of 14 mA and efficiency of 0.89 W/A, in contrast to the conventional laser element having a threshold value of 34 mA and efficiency of 0.62 W/A. The smaller threshold value of the inventive laser element 1 conceivably results from the narrower stripe width and the structure of effective refractivity waveguide which suppresses the light absorption. At 60° C., the laser element 1 of this embodiment has a threshold value of 38 mA and efficiency of 0.78 W/A, in contrast to the conventional laser element having a threshold value of 58 mA and efficiency of 0.48 W/A. The inventive laser element 1 is superior over the conventional counterpart also at 60° C., which results from the structure of effective refractivity waveguide, while retaining the tensile strain, which reduces the threshold value and improves the efficiency.

FIGS. 20A and 20B show the far field pattern of the semiconductor laser element 1. The inventive laser element 1 has a vertical spread angle θ⊥ of 15.8°, in contrast to 30.2° of the conventional laser element. The inventive laser element 1 has a horizontal spread angle θ// of 14.3°, in contrast to 7.4° of the conventional laser element. Accordingly, the inventive laser element 1 has an aspect ratio of 1.10, which produces a beam spot close on a true circle, in contrast to 4.08 of the conventional laser element.

The laser oscillation wavelength is 638 nm at 25° C. Consequently, there is accomplished a semiconductor laser element 1 of 630-nm band which produces a beam spot close on a true circle.

Although the present invention has been described in connection with the specific embodiments, the invention is not confined to these embodiments, but various alterations are obviously possible without departing from the essence of the invention.

Among the affairs of the present invention disclosed in this specification, the major effectiveness is briefed as follows.

(1) The inventive semiconductor laser element of 630-nm band can attain an aspect ratio of beam far field pattern of 1.6 or less, or possibly 1.2 or less.

(2) The inventive rotational laser equipment which incorporates the semiconductor laser element of 630-nm band, with the aspect ratio being made close on 1, can be reduced in size and manufacturing cost.

1. A semiconductor laser element comprising:
a GaAs substrate of a first conductivity type;
a cladding layer of the first conductivity type which is made from AlGaInP and formed over the main surface of said GaAs substrate;
an active layer which is formed over said cladding layer of the first conductivity type to have a quantum well structure including well layers of GaInP and a barrier layer of AlGaInP, said well layers being tensile strain layers;
a cladding layer of a second conductivity type which is made from AlGaInP and formed over said active layer; and
a contact layer of the second conductivity type which is made from GaAs and formed over said cladding layer of the second conductivity type,
said active layer having its light emission section emitting a laser beam from both end faces thereof, said light emission section of active layer being adjoined on both sides thereof by a semiconductor layer which is low in refractivity relative to said active layer, thereby structuring an effective refractivity waveguide.

2. A semiconductor laser element according to claim 1, wherein said well layers of quantum well structure have a total thickness of 25 nm or less.

3. A semiconductor laser element according to claim 1, wherein said laser beam has a wavelength of 630-nm band.

4. A semiconductor laser element comprising:
a GaAs substrate of a first conductivity type;
a cladding layer of the first conductivity type which is made from AlGaInP and formed over the main surface of said GaAs substrate;
an active layer which is formed over said cladding layer of the first conductivity type to have a quantum well structure including well layers of GaInP and a barrier layer of AlGaInP, said well layers being tensile strain layers;
a cladding layer of a second conductivity type which is made from AlGaInP and formed over said active layer; and
a contact layer of the second conductivity type which is made from GaAs and formed over said cladding layer of the second conductivity type,
said active layer having its light emission section emitting a laser beam from both end faces thereof, said laser beam having an aspect ratio of far field pattern of 1.6 or less.

5. A semiconductor laser element according to claim 4, wherein said light emission section of active layer is adjoined on both sides thereof by a semiconductor layer which is low in refractivity relative to said active layer, thereby structuring an effective refractivity waveguide.

6. A semiconductor laser element according to claim 4, wherein said well layers of quantum well structure have a total thickness of 25 nm or less.

7. A semiconductor laser element according to claim 4, wherein said laser beam has a wavelength of 630-nm band.

8. A semiconductor laser element comprising:
a GaAs substrate of a first conductivity type;
a cladding layer of the first conductivity type which is made from AlGaInP and formed over the main surface of said GaAs substrate;
an active layer which is formed over said cladding layer of the first conductivity type to have a quantum well structure including well layers of GaInP and of two periods or less and a barrier layer of AlGaInP, said well layers being tensile strain layers;
a cladding layer of a second conductivity type which is made from AlGaInP and formed over said active layer; and
a contact layer of the second conductivity type which is made from GaAs and formed over said cladding layer of the second conductivity type,
said active layer having its light emission section emitting a laser beam from both end faces thereof, said light emission section of active layer being adjoined on both sides thereof by a semiconductor layer which is low in refractivity relative to said active layer, thereby structuring an effective refractivity waveguide.

9. A semiconductor laser element according to claim 8, wherein said GaAs substrate has its main surface stepped across a slope, the portion of said active layer over the slope being the light emission section, the other portion of said active layer outside of and over both sides of the light emission section being the low-refractivity semiconductor layer.

10. A semiconductor laser element according to claim 9, wherein the main surface of said GaAs substrate is oblique by 7° from the crystal plane (100) toward the crystal axis [111], and the slope is oblique by 12.5° and is a (411)A-plane equivalent crystal plane.

11. A semiconductor laser element according to claim 9, wherein the main surface of said GaAs substrate is oblique by 7° from the crystal plane (100) toward the crystal axis [111], and the slope is oblique by 18.2° and is a (311)A-plane equivalent crystal plane.

12. A semiconductor laser element according to claim 9 further including between said active layer and said contact layer:
a first cladding layer of the second conductivity type which is made from AlGaInP and formed over said active layer;
a blocking layer which is made from AlGaInP, while including Zn and Se, and formed over said first cladding layer; and
a second cladding layer of the second conductivity type which is made from AlGaInP, higher in carrier concentration than said first cladding layer and formed over said blocking layer,
the portion of said blocking layer over the slope having the second conductivity type, the other portion of said blocking layer outside of the slope having the first conductivity type.

13. A semiconductor laser element according to claim 8, wherein said active layer has a stripe structure to emit a laser beam from both end faces of the stripe, the stripe being adjoined on both sides thereof by a semiconductor layer which is different from said active layer and is low in refractivity relative to said active layer.

14. A semiconductor laser element according to claim 13 comprising:
a cladding layer of the first conductivity type which is made from AlGaInP and formed over said GaAs substrate of the first conductivity type, and an etching stop layer of the first conductivity type which is made from GaInP and formed over said cladding layer;
said cladding layer of the first conductivity type, said active layer, and a cladding layer of the second conductivity type made from AlGaInP which are formed sequentially by being striped and laminated over said etching stop layer;
an AlGaAs layer of the second conductivity type and an AlGaAs layer or AlGaInP layer of the first conductivity type which are formed sequentially by being laminated over said etching stop layer on both sides of the stripe; and
a cladding layer and a contact layer of the second conductivity type which are made from AlGaInP and formed sequentially to cover said striped cladding layer and said AlGaAs layer or AlGaInP layer of the first conductivity type,
said striped active layer having its light emission section covered over both sides thereof with said AlGaAs layer of the second conductivity type.

15. A semiconductor laser element according to claim 14, wherein said cladding layer of the first conductivity type, said active layer, and said cladding layer of the second conductivity type have their width of stripe section made constant or narrowed progressively from said cladding layer of the second conductivity type toward said cladding layer of the first conductivity type.

16. A semiconductor laser element according to claim 8, wherein said laser beam has an aspect ratio of far field pattern of 1.6 or less.

17. A semiconductor laser element according to claim 8, wherein said well layers of quantum well structure have a total thickness of 25 nm or less.

18. A semiconductor laser element according to claim 6, wherein said laser beam has a wavelength of 630-nm band.

19. A semiconductor laser element according to claim 8, wherein said well layers have a tensile strain value ranging from −0.1% to −1.5% approximately.

20. A semiconductor laser element according to claim 8, wherein said light emission section has a width ranging from 0.5 μm to 2.0 μm appropriately.

21. An optical-electronic device which projects a laser beam emitted by a semiconductor laser element onto a subject body through a beam rectifying optical system, thereby marking a position on said subject body, said semiconductor laser element comprising:
a GaAs substrate of a first conductivity type;
a cladding layer of the first conductivity type which is made from AlGaInP and formed over the main surface of said GaAs substrate,
an active layer which is formed over said cladding layer of the first conductivity type to have a quantum well structure including well layers of GaInP and of two periods or less and a barrier layer of AlGaInP, said well layers being tensile strain layers; and
a cladding layer of a second conductivity type which is made from AlGaInP and formed over said active layer,
said active layer having its light emission section emitting a laser beam from both end faces thereof, said light emission section of active layer being adjoined on both sides thereof by a semiconductor layer which is low in refractivity relative to said active layer, thereby structuring an effective refractivity waveguide, and
said laser beam having an aspect ratio of far field pattern of 1.6 or less and having a wavelength of 630-nm band.
